(19) United States
(12) Patent Application Publication
(10) Pub. No.: US 2024/0324225 A1
(43) Pub. Date: Sep. 26, 2024

(54) STORAGE TRANSISTOR OF CHARGE-TRAPPING NON-VOLATILE MEMORY

(71) Applicant: eMemory Technology Inc., Hsin-Chu (TW)

(72) Inventors: Chun-Hsiao LI, Hsinchu County (TW); Chia-Jung HSU, Hsinchu County (TW); Tsung-Mu LAI, Hsinchu County (TW)

(21) Appl. No.: 18/586,595

(22) Filed: Feb. 26, 2024

Related U.S. Application Data
(60) Provisional application No. 63/453,182, filed on Mar. 20, 2023.

(51) Int. Cl. H10B 43/35; H01L 21/28; H01L 29/423; H01L 29/792

(52) U.S. Cl. CPC H10B 43/35; H01L 29/40117; H01L 29/4234; H01L 29/792

(57) ABSTRACT

A storage transistor of a charge-trapping non-volatile memory includes a semiconductor substrate, a well region, a gate structure, a spacer, a first doped region and a second doped region. The well region is formed in a surface of the semiconductor substrate. The first doped region and the second doped region are formed in the well region. The gate structure includes a first tunneling layer, a second tunneling layer, a third tunneling layer, a trapping layer, a blocking layer and a gate layer. The first tunneling layer is contacted with the surface of the well region. The second tunneling layer covers the first tunneling layer. The third tunneling layer covers the second tunneling layer. The trapping layer covers the third tunneling layer. The blocking layer covers the trapping layer. The gate layer covers the blocking layer.

This application claims the benefit of U.S. provisional application Ser. No. 63/453,182, filed Mar. 20, 2023, the subject matters of which are incorporated herein by references.

### FIELD OF THE INVENTION

The present invention relates to a non-volatile memory, and more particularly to a storage transistor of a charge-trapping non-volatile memory and a gate structure of the storage transistor.

### BACKGROUND OF THE INVENTION

Non-volatile memories have been widely used in a variety of electronic products. After the non-volatile memory is powered off, the stored data is still retained. Generally, a charge-trapping non-volatile memory comprises a storage transistor. The storage state of the storage transistor is determined according to the result of judging whether charges (e.g., electrons) are stored in the storage transistor.

FIG. 1A is a schematic cross-sectional view illustrating an N-type storage transistor of a conventional charge-trapping non-volatile memory. FIG. 1B is a schematic cross-sectional view illustrating a P-type storage transistor of a conventional charge-trapping non-volatile memory. The structure of the N-type storage transistor and the structure of the P-type storage transistor are similar.

Please refer to FIG. 1A. A gate structure 120 is formed on the surface of a P-well region 100 of a semiconductor substrate. The gate structure 120 comprises a tunneling layer 122, a trapping layer 124, a blocking layer 126 and a gate layer 128. The tunnelling layer 122 and the blocking layer 126 are made of silicon dioxide (SiO₂), the trapping layer 124 is made of silicon nitride (SiN), and the gate layer 128 is made of polysilicon. A spacer 132 is formed on the lateral side of the gate structure 120 to surround the gate structure 120.

Then, a doping process is performed using the gate structure 120 as a mask. As shown in FIG. 1A, two n-type doped regions 103 and 105 are formed under the surface of the P-well region 100. The n-type doped regions 103 and 105 are respectively located beside two sides of the gate structure 120. In addition, the gate layer 128 is an n-type polysilicon gate layer. Consequently, the P-well region 100, the n-type doped region 103, the n-type doped region 105, the gate structure 120 and the spacer 132 are collaboratively formed as an n-type storage transistor Msn.

In the n-type storage transistor Msn, the trapping layer 124 of the gate structure 120 can store charges (e.g., the electrons). In case that no charges are stored in the trapping layer 124 of the n-type storage transistor Msn, the n-type storage transistor Msn is in a first storage state. In case that charges are stored in the trapping layer 124 of the n-type storage transistor Msn, the n-type storage transistor Msn is in a second storage state.

For example, after a program action is performed, charges are transmitted from a channel region of the n-type storage transistor Msn to the trapping layer 124 through the tunneling layer 122 and trapped in the trapping layer 124. Consequently, the storage state of the n-type storage transistor Msn is changed from the first storage state to the second storage state. After an erase action is performed, charges are ejected from the trapping layer 124 to the P-well region 100. Consequently, the storage state of the n-type storage transistor Msn is changed from the second storage state to the first storage state. Moreover, when a read action is performed, the storage state of the n-type storage transistor Msn is determined according to the magnitude of the read current generated by the n-type storage transistor Msn.

The process of forming the P-type storage transistor is similar to the process of forming the N-type storage transistor. Please refer to FIG. 1B. Two p-type doped regions 143 and 145 are formed under the surface of an N-well region 140 of the semiconductor substrate. A gate structure 150 is formed over the surface of the N-well region 140. In addition, the gate structure 150 is arranged between the p-type doped regions 143 and 145. In addition, a spacer 162 is formed on the lateral side of the gate structure 150 to surround the gate structure 150.

Similarly, the gate structure 150 comprises a tunneling layer 152, a trapping layer 154, a blocking layer 156 and a gate layer 158. The tunnelling layer 152 and the blocking layer 156 are made of silicon dioxide (SiO₂), the trapping layer 154 is made of silicon nitride (SiN), and the gate layer 158 is made of polysilicon. In addition, the gate layer 158 is a p-type gate layer. Consequently, the N-well region 140, the p-type doped region 143, the p-type doped region 145, the gate structure 150 and the spacer 162 are collaboratively formed as a p-type storage transistor Msp.

Similarly, after the program action is performed, the storage state of the p-type storage transistor Msp is changed from the first storage state to the second storage state. After the erase action is performed, the storage state of the p-type storage transistor Msp is changed from the second storage state to the first storage state. Moreover, when the read action is performed, the storage state of the p-type storage transistor can be determined.

FIG. 1C is an energy band diagram of the conventional n-type storage transistor in the first storage state. FIG. 1D is an energy band diagram of the conventional p-type storage transistor in the first storage state. In case that no charges are stored in the trapping layer 124 of the n-type storage transistor Msn, the n-type storage transistor Msn is in the first storage state. Similarly, in case that no charges are stored in the trapping layer 154 of the p-type storage transistor Msp, the p-type storage transistor Msp is in the first storage state.

Please refer to FIG. 1C. After the alignment of the Fermi level E_{F}, the energy band of the P-well region 100 (i.e., the conduction band E_{C} and the valence band E_{V}) bends downwardly at the position near the interface between the P-well region 100 and the tunneling layer 122. Consequently, the energy band of the tunneling layer 122 tilts toward the left side. That is, the energy band of the tunneling layer 122 tilts in the direction toward the trapping layer 124. In addition, the energy band of the trapping layer 124 also tilts toward the left side.

Please refer to FIG. 1D. The energy band of the N-well region 140 bends upwardly at the position near the interface between the N-well region 140 and the tunneling layer 152. The energy band of the tunneling layer 152 tilts toward the right side. That is, the energy band of the tunneling layer 152 tilts toward the N-well region 140. In addition, the energy band of the trapping layer 154 tilts toward the right side.

FIG. 1E is an energy band diagram of the conventional n-type storage transistor in the second storage state. FIG. 1F is an energy band diagram of the conventional p-type storage transistor in the second storage state. In case that charges are stored in the trapping layer 124 of the n-type storage transistor Msn, the n-type storage transistor Msn is in the second storage state. Similarly, in case that charges are stored in the trapping layer 154 of the p-type storage transistor Msp, the p-type storage transistor Msp is in the second storage state.

Please refer to FIG. 1E. When electrons are stored in the trapping layer 124, the energy band of the P-well region 100 (i.e., the conduction band E_{C} and the valence band E_{V}) bends upwardly at the position near the interface between the P-well region 100 and the tunneling layer 122. The energy band of the tunneling layer 122 tilts toward the right side. That is, the energy band of the tunneling layer 122 tilts toward the P-well region 100. In addition, the energy band of the trapping layer 124 also tilts toward the right side.

Please refer to FIG. 1F. The energy band of the N-well region 140 bends upwardly at the position near the interface between the N-well region 140 and the tunneling layer 152. The energy band of the tunneling layer 152 tilts towards the right side. That is, the energy band of the tunneling layer 152 tilts toward the N-well region 140. In addition, the energy band of the trapping layer 154 also tilts toward the right side.

After electrons are trapped in the trapping layers 124 and 154, the electrons in the trapping layers 124 and 154 may escape to the P-well region 100 or the N-well region 140. For example, electrons escape through a direct tunneling (DT) effect and a trap-assisted tunneling (TAT) effect. Generally, the electrons in the shallow trap are transferred through the tunneling layers 122 and 152 according to the DT effect. In addition, the electrons in the deep trap are transferred through the tunneling layers 122 and 152 according to the TAT effect.

Please refer to FIGS. 1E and 1F again. When the DT effect occurs, the electrons stored in the shallow traps of the trapping layers 124 and 154 are directly transmitted to the P-well region 100 or the N-well region 140 through the tunneling layers 122 and 152. When the TAT effect occurs, the electrons stored in the deep traps of the trapping layers 124 and 154 are firstly trapped in the tunneling layers 122 and 152, and then the electrons are transmitted to the P-well region 100 or the N-well region 140.

Please refer to FIGS. 1E and 1F again. In the second storage state, the energy band of the tunneling layer 152 of the p-type storage transistor Msp tilts greatly. Consequently, electrons will escape from the tunneling layer 152 more easily. In other words, the data retention capability of the p-type storage transistor is inferior, and the data retention capability of the N-type storage transistor is better.

In order to improve the data retention capability of the conventional p-type storage transistor Msp, it is necessary to increase the thickness of the tunneling layer 152 to avoid the electron escape problem. However, after the thickness of the tunneling layer 152 is increased, the data endurance of the p-type storage transistor Msp is significantly reduced. For example, after the program/erase count of the p-type storage transistor Msp exceeds 800, the gate structure 150 of the p-type storage transistor Msp deteriorates significantly. Consequently, the gate structure 150 is unable to store electrons.

Moreover, since the thickness of the tunneling layer 152 of the p-type storage transistor Msp is increased, a higher erase voltage is required for performing the erase action. However, the semiconductor components manufactured by advanced semiconductor process cannot withstand the large voltage stress. Consequently, the conventional p-type storage transistor Msp cannot be manufactured by using advanced semiconductor process.

### SUMMARY OF THE INVENTION

The present invention provides a gate structure of a storage transistor. Consequently, the data retention capability and the data endurance of the p-type storage transistor are enhanced. In addition, the p-type storage transistor can be manufactured by using the advanced semiconductor process.

An embodiment of the present invention provides a storage transistor of a charge-trapping non-volatile memory. The storage transistor includes a semiconductor substrate, a well region, a gate structure, a spacer, a first doped region and a second doped region. The well region is formed in a surface of the semiconductor substrate. The gate structure is formed over a surface of the well region. The spacer is formed on a lateral side of the gate structure. In addition, the gate structure is surrounded by the spacer. The first doped region and the second doped region are formed in the well region. In addition, the first doped region and the second doped region are respectively located beside two sides of the gate structure. The gate structure includes a first tunneling layer, a second tunneling layer, a third tunneling layer, a trapping layer, a blocking layer and a gate layer. The first tunneling layer is contacted with the surface of the well region. The first tunneling layer is made of oxide. The second tunneling layer covers the first tunneling layer. The second tunneling layer is made of nitride. The third tunneling layer covers the second tunneling layer. The third tunneling layer is made of oxynitride. The trapping layer covers the third tunneling layer. The blocking layer covers the trapping layer. The gate layer covers the blocking layer. The first tunneling layer, the second tunneling layer and the third tunneling layer are made of different materials. A work function of the gate layer is higher than a work function of the well region.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic cross-sectional view illustrating an N-type storage transistor of a conventional charge-trapping non-volatile memory;

FIG. 1B (prior art) is a schematic cross-sectional view illustrating a P-type storage transistor of a conventional charge-trapping non-volatile memory;

FIG. 1C (prior art) is an energy band diagram of the conventional n-type storage transistor in the first storage state;

FIG. 1D (prior art) is an energy band diagram of the conventional p-type storage transistor in the first storage state;

FIG. 1E (prior art) is an energy band diagram of the conventional n-type storage transistor in the second storage state;

FIG. 1F (prior art) is an energy band diagram of the conventional p-type storage transistor in the second storage state;

FIG. 2A is a schematic cross-sectional view illustrating an N-type storage transistor of a charge-trapping non-volatile memory according to an embodiment of the present invention;

FIG. 2B is an energy band diagram of the p-type storage transistor of the present invention in a first storage state;

FIG. 2C is an energy band diagram of the p-type storage transistor of the present invention in a second storage state;

FIG. 2D is an energy band diagram of the p-type storage transistor when a program action is performed; and

FIG. 2E is an energy band diagram of the p-type storage transistor when an erase action is performed.

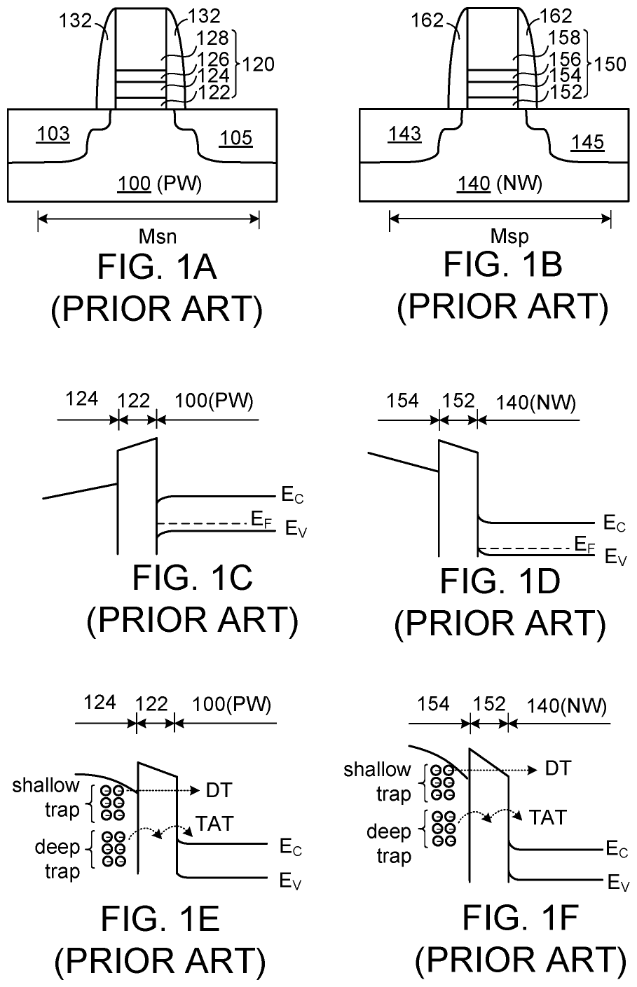

### DETAILED DESCRIPTION OF PREFERRED EMBODIMENTS

The present invention provides a p-type storage transistor of a charge-trapping non-volatile memory. The p-type storage transistor of the charge-trapping non-volatile memory has a novel gate structure. Consequently, the data retention capability and the data endurance of the p-type storage transistor are enhanced.

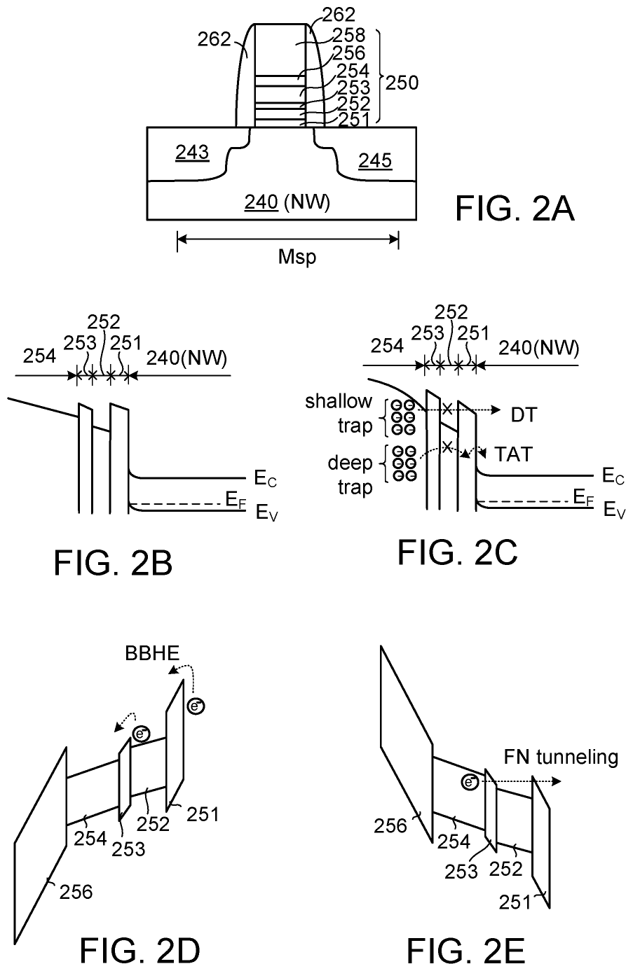

FIG. 2A is a schematic cross-sectional view illustrating a p-type storage transistor of a charge-trapping non-volatile memory according to the embodiment of the present invention. As shown in FIG. 2A, a gate structure 250 is formed over the surface of an N-well region 240 of a semiconductor substrate. A spacer 262 is formed on the lateral side of the gate structure 250 to surround the gate structure 250. The gate structure 250 comprises a first tunneling layer 251, a second tunneling layer 252, a third tunneling layer 253, a trapping layer 254, a blocking layer 256 and a gate layer 258, which are stacked on each other. The first tunneling layer 251 is contacted with the surface of the N-well region 240. The second tunneling layer 252 covers the first tunneling layer 251. The third tunneling layer 253 covers the second tunneling layer 252. The trapping layer 254 covers the third tunneling layer 253. The blocking layer 256 covers the trapping layer 254. The gate layer 258 covers the blocking layer 256. Moreover, the gate layer 258 is made of polysilicon.

In addition, two p-type doped regions 243 and 245 are formed under the surface of the N-well region 240. The n-type doped regions 243 and 245 are respectively located beside two sides of the gate structure 250. In addition, the gate layer 258 is a p-type polysilicon gate layer. Consequently, the N-well region 240, the p-type doped region 243, the p-type doped region 245, the gate structure 250 and the spacer 262 are collaboratively formed as a p-type storage transistor Msp.

In the first embodiment, the three tunneling layers 251, 252 and 253 are made of different materials. For example, the first tunneling layer 251 is made of oxide, the second tunneling layer 252 is made of nitride, and the third tunneling layer 253 is made of oxynitride. Moreover, the trapping layer 254 is made of nitride, and the blocking layer 256 is made of oxide. For example, the first tunnelling layer 251 is made of silicon dioxide (SiO₂), the second tunnelling layer 252 is made of silicon nitride (SiN), the third tunnelling layer 253 is made of silicon oxynitride (SiON), the trapping layer 254 is made of silicon nitride (SiN), and the blocking layer 256 is made of silicon dioxide (SiO₂).

In this embodiment, the thickness of the trapping layer 254 is larger than the thickness of the blocking layer 256, the thickness of the blocking layer 256 is larger than the thickness of the second tunneling layer 252, the thickness of the second tunneling layer 252 is larger than the thickness of the first tunneling layer 251, and the thickness of the first tunneling layer 251 is larger than the thickness of the third tunneling layer 253. For example, the overall thickness of the first tunneling layer 251, the second tunneling layer 252 and the third tunneling layer 253 is smaller than 60 Å (angstroms). The thickness of the third tunneling layer 253 is smaller than 20 Å, e.g., approximately 5˜7 Å. The thickness of the second tunneling layer 252 is smaller than 50 Å, e.g., approximately 30˜35 Å. The thickness of the first tunneling layer 251 is smaller than 30 Å, e.g., approximately 10˜15 Å.

FIG. 2B is an energy band diagram of the p-type storage transistor of the present invention in a first storage state. FIG. 2C is an energy band diagram of the p-type storage transistor of the present invention in a second storage state. In FIGS. 2B and 2C, no bias voltages are provided to the p-type transistor Msp. When no charges are stored in the trapping layer 254 of the p-type storage transistor Msp, the p-type storage transistor Msp is in the first storage state. Whereas, in case that charges are stored in the trapping layer 254 of the p-type storage transistor Msp, the p-type storage transistor Msp is in the second storage state.

Please refer to FIG. 2B. The conduction band E_{C} and the valence band E_{V} of the N-well region 240 bend upwardly at the position near the interface between the N-well region 240 and the first tunneling layer 251. The energy bands of the first tunneling layer 251, the second tunneling layer 252 and the third tunneling layer 253 tilt toward the right side. In addition, the energy band of the trapping layer 254 also tilts toward the right side.

Please refer to FIG. 2C. When charges are stored in the trapping layer 254, the energy band of the N-well region 240 bends upwardly at the position near the interface between the N-well region 240 and the first tunneling layer 251. The energy band of the first tunneling layer 251, the second tunneling layer 252 and the third tunneling layer 253 tilts towards the right side. In addition, the energy band of the trapping layer 254 also tilts toward the right side.

As shown in FIG. 2C, the storage transistor of the present invention is further equipped with the third tunneling layer 253. Due to the barrier formed by the third tunneling layer 253, the probability of escaping the charges through the DT effect and TAT effect will be effectively restrained. In other words, the data retention capability of the p-type storage transistor Msp is enhanced.

By providing proper bias voltage to the p-type storage transistor, a program action or an erase action can be selectively performed on the p-type storage transistor. FIG. 2D is an energy band diagram of the p-type storage transistor when a program action is performed. FIG. 2E is an energy band diagram of the p-type storage transistor when an erase action is performed.

When the program action is performed, the gate layer 258 of the p-type storage transistor Msp receives a control voltage. Consequently, the p-type storage transistor Msp is turned on. The channel region between the p-type doped region 243 and the p-type doped region 245 generates a program current. In addition, a band-to-band tunneling-induced hot carrier injection effect (also referred as a BBHE effect) is generated. Under this circumstance, the injected electrons are trapped in the trapping layer 254. Consequently, the storage state of the p-type storage transistor is changed from the first storage state to the second storage state.

Please refer to FIG. 2D. When the program action is performed, the energy band tilts toward the left side. Since the third tunneling layer 253 is made of oxynitride and the first tunneling layer 251 is made of oxide, the barrier height of the third tunneling layer 253 is lower than the barrier height of the first tunneling layer 251. Consequently, after electrons are transferred through the first tunneling layer 251, the electrons can be transferred through the third tunneling layer 253 easily and then trapped in the trapping layer 254. In other words, the program efficiency of the p-type storage transistor is effectively enhanced.

When the erase action is performed, the gate layer 258 of the p-type storage transistor Msp receives an erase voltage V_{EE}. The erase voltage V_{EE} has a negative voltage value. The N-well region 240 receives the ground voltage (0V). For example, the magnitude of the erase voltage V_{EE} is 12V. That is, the erase voltage V_{EE} is −12V. Under this circumstance, charges (i.e., electrons) stored in the trapping layer 254 is transferred through the N-well region 240. Consequently, the storage state of the p-type storage transistor Msp is changed from the second storage state to the first storage state.

Please refer to FIG. 2E. When the erase action is performed, the energy band tilts toward the right side. Since the barrier height of the third tunneling layer 253 is lower than the barrier height of the first tunneling layer 251, a Fowler-Nordheim (FN) tunneling effect is generated. Due to the FN tunneling effect, electrons can be ejected from the N-well region 240 easily. In other words, the erase efficiency of the p-type storage transistor is effectively enhanced.

Moreover, in case that the storage transistor is the p-type transistor, the work function of the p-type polysilicon gate layer 258 is about 5.1 eV, and the work function of the N-well region 240 is about 4.4 eV. In the energy band diagram, each of the tunneling layers 251, 252 and 253 has the lower barrier. Consequently, the erase action can be performed more easily. In other words, if the work function of the gate layer 258 is increased, the FN tunneling effect can be enhanced when the erase action is performed.

Of course, as long as the work function of the gate layer 258 is higher than the work function of the N-well region 240, the material of the gate layer 258 of the p-type storage transistor Msp is not restricted. For example, in some other embodiments, the gate layer 258 is made of a metallic material with the higher work function. That is, the gate layer 258 is a metal gate layer. Due to the cooperation of the metal gate layer 258 and the N-well region 240, the FN tunneling effect is also enhanced when the erase action is performed.

In an embodiment, the efficiency of FN tunneling effect during the erase action is enhanced by changing the material of the blocking layer 256. For example, the material of the first tunneling layer 251 in the p-type storage transistor Msp is silicon dioxide (SiO₂) with the dielectric constant (also referred K value) of 3.9. In some other embodiments, the blocking layer 256 made of a high-K material is feasible, and the K value of the blocking layer 256 is higher than twice the K value of the first tunneling layer 251. Since the blocking layer 256 has the high K value, the intensity of the electric field in the first tunneling layer 251 is stronger during the erase action. Consequently, the FN tunneling effect can be generated more easily. In other words, the material with the K value higher than 7.8 is suitably used as the material of the blocking layer 256.

In addition to the silicon nitride (SiN), the trapping layer 254 may be made of any other appropriate high-K material. For example, in some other embodiments, the trapping layer 254 is made of hafnium dioxide (HfO₂), zirconium dioxide (ZrO₂), titanium dioxide (TiO₂), hafnium silicate (HfSiO₄), lanthanum oxide (La₂O₃), lanthanum aluminate (LaAlO₃) or yttrium oxide (Y₂O₃).

In an embodiment, each of the trapping layer 254 and the second tunneling layer 252 in the p-type storage transistor Msp is made of nitride, e.g., silicon nitride. In fact, the nitride constituent in the trapping layer 254 and the nitride constituent in the second tunneling layer 252 may be slightly different. In silicon nitride material, the higher silicon content is correlated with the high refractive index, and the higher nitrogen content is correlated with the low refractive index. In other words, the nitride material with the higher refractive index may be considered as the Si-rich nitride, and the nitride material with the lower refractive index may be considered as the N-rich nitride. For example, the trapping layer 254 is a N-rich nitride with a refractive index lower than 2.05, and the second tunneling layer 252 is a Si-rich nitride with a refractive index higher than 2.1.

From the above descriptions, the present invention provides a p-type storage transistor of a charge-trapping non-volatile memory. The gate structure of the p-type storage transistor is specially designed. Consequently, the data retention capability of the p-type storage transistor is increased. In addition, the program efficiency during the program action and the erase efficiency during the erase action are enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A storage transistor of a charge-trapping non-volatile memory, the storage transistor comprising:
a semiconductor substrate;
a well region formed in a surface of the semiconductor substrate;
a gate structure formed over a surface of the well region;
a spacer formed on a lateral side of the gate structure, wherein the gate structure is surrounded by the spacer; and
a first doped region and a second doped region formed in the well region, and respectively located beside two sides of the gate structure,
wherein the gate structure comprises:
a first tunneling layer contacted with the surface of the well region, wherein the first tunneling layer is made of oxide;
a second tunneling layer covering the first tunneling layer, wherein the second tunneling layer is made of nitride;
a third tunneling layer covering the second tunneling layer, wherein the third tunneling layer is made of oxynitride;
a trapping layer covering the third tunneling layer;
a blocking layer covering the trapping layer; and
a gate layer covering the blocking layer,
wherein the first tunneling layer, the second tunneling layer and the third tunneling layer are made of different materials, and a work function of the gate layer is higher than a work function of the well region.

2. The storage transistor as claimed in claim 1, wherein the well region is an n-type well region, the first doped region and the second doped region are p-type doped regions, and the storage transistor is a p-type storage transistor.

3. The storage transistor as claimed in claim 1, wherein the first tunneling layer is made of silicon dioxide, the second tunneling layer is made of silicon nitride, and the third tunneling layer is made of silicon oxynitride.

4. The storage transistor as claimed in claim 1, wherein the gate layer is made of a metallic material, and the gate layer is a metal gate layer, wherein a work function of the metal gate layer is higher than the work function of the well region.

5. The storage transistor as claimed in claim 1, wherein the gate layer is made of polysilicon, and the gate layer is a p-type polysilicon gate layer, wherein a work function of the p-type polysilicon gate layer is higher than the work function of the well region.

6. The storage transistor as claimed in claim 1, wherein the second tunneling layer is made of silicon-rich nitride.

7. The storage transistor as claimed in claim 6, wherein a refractive index of the second tunneling layer is higher than 2.1.

8. The storage transistor as claimed in claim 1, wherein the trapping layer is made of nitrogen-rich nitride.

9. The storage transistor as claimed in claim 8, wherein a refractive index of the trapping layer is lower than 2.05.

10. The storage transistor as claimed in claim 1, wherein the trapping layer is made of silicon nitride.

11. The storage transistor as claimed in claim 1, wherein the trapping layer is made of hafnium dioxide, zirconium dioxide, titanium dioxide, hafnium silicate, lanthanum oxide, lanthanum aluminate or yttrium oxide.

12. The storage transistor as claimed in claim 1, wherein the trapping layer is thicker than the blocking layer, the blocking layer is thicker than the second tunneling layer, the second tunneling layer is thicker than the first tunneling layer, and the first tunneling layer is thicker than the third tunneling layer.

13. The storage transistor as claimed in claim 1, wherein the thickness of the third tunneling layer is smaller than 20 angstroms.

14. The storage transistor as claimed in claim 1, wherein the first tunneling layer has a first dielectric constant, and the blocking layer has a second dielectric constant, wherein the second dielectric constant is larger than twice the first dielectric constant.
